(19) United States
(12) Patent Application Publication
(10) Pub. No.: US 2006/0017137 A1
(43) Pub. Date: Jan. 26, 2006

(54) Semiconductor device and its manufacturing method

(75) Inventor: Toshiaki Iwamatsu, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 11/185,841

(22) Filed: Jul. 21, 2005

(30) Foreign Application Priority Data
Jul. 22, 2004 (JP) 2004-213876

(51) Int. Cl. H01L 29/04

(52) U.S. Cl. 257/627

(57) ABSTRACT

A semiconductor device and its manufacturing method are achieved which are capable of mixing a plurality of different crystal orientations in SOI substrate surfaces and controlling increase of leakage current into substrates and increase in power consumption in each area. An SOI substrate is fabricated by bonding two semiconductor wafers together so that the same <110> crystal orientations of those wafers are displaced at a predetermined angle (e.g., 45 degrees) with respect to each other. Part of the SOI substrate surface is then etched to a buried insulating layer, in which part epitaxial growth is conducted. Then, using the SIMOX technique, a buried oxide film is also formed in the area where an epitaxial growth layer is formed, so that the SOI structure is formed in each area.

### BACKGROUND OF THE INVENTION

1. Field of the Invention

The present invention relates to a semiconductor device with buried insulating layers, and its manufacturing method.

2. Description of the Background Art

As the integration rate and functionality of LSI (Large Scale Integration) increase, MOS (Metal Oxide Semiconductor) transistors as constituents of LSI become finer. To further enhance current drive capability of MOS transistors, there are techniques for fabricating p- and n-channel MOS transistors on semiconductor substrate surfaces with different crystal orientations (cf. Japanese Patent Application Laid-open Nos. 5-90117 (1993) and 4-372166 (1992)).

The reason for using different crystal orientations for p- and n-channel MOS transistors is because forming p-channel MOS transistors on a (110) plane causes transistor channels to be oriented in the <110> direction where hole mobility is high, resulting in an increase in current drive capability; and forming n-channel MOS transistors on a (100) plane causes transistor channels to be oriented in the <100> direction where electron mobility is high, resulting in an increase in current drive capability.

M. Yang et al. in their article titled, “High Performance CMOS Fabricated on Hybrid Substrate With Different Crystal Orientations,” IEDM 2003, pp. 453-456, disclose a technique for enhancing current drive capability of both p- and n-channel MOS transistors by forming, on part of SOI (Silicon On Insulator) substrate surfaces, epitaxial growth layers having different crystal orientation from SOI layers, and then fabricating for example p-channel MOS transistors on the SOI layers and n-channel MOS transistors on the epitaxial growth layers.

More specifically, according to this technique, (110) and (100) crystal planes are mixed in SOI substrate surfaces, so that p-channel MOS transistors can be formed on the (110) crystal plane and n-channel MOS transistors on the (100) crystal plane. Thereby, the p-channel MOS transistor channel is oriented in the <110> direction, and the n-channel MOS transistor channel is oriented in the <100> direction.

In connection with the invention of this application, there is also another prior-art document, namely, Japanese Patent Application Laid-open No. 2000-243973.

In the above technique disclosed by M. Yang et al., the substrate is similar in structure to the standard bulk substrate, with no buried oxide film in the area where the epitaxial growth layer is formed. Thus, it is impossible, in the area where the epitaxial growth layer is formed, to control increase of leakage current into substrates and increase in power consumption.

### SUMMARY OF THE INVENTION

It is an object of the present invention to provide a semiconductor device and its manufacturing method which are capable of mixing a plurality of different crystal orientations in SOI substrate surfaces and controlling increase of leakage current into substrates and increase in power consumption in each area.

According to a first aspect of the present invention, the semiconductor device includes a supporting substrate, a first buried insulating layer, a second buried insulating layer, a first SOI (Semiconductor On Insulator) layer, and a second SOI layer. The supporting substrate has a surface divided into at least first and second regions. The first buried insulating layer is provided on the surface of the supporting substrate in the first region. The second buried insulating layer is provided on the surface of the supporting substrate in the second region. The first SOI layer is provided on the first buried insulating layer. The second SOI layer is provided on the second buried insulating layer. The first and second SOI layers have different crystal orientations along a predetermined direction.

The above semiconductor device includes the first and second buried insulating layers provided respectively on the surface of the supporting substrate in the first and second regions, respectively, and the first and second SOI layers provided on the first and second buried insulating layers, respectively. And, the first and second SOI layers have different crystal orientations along a predetermined direction. Thus, it is possible to mix a plurality of different crystal orientations in the surface of the SOI substrate and to control increase of leakage current into the substrate and increase in power consumption.

According to a second aspect of the present invention, the semiconductor device manufacturing method includes the following steps (a) to (f). The step (a) is to form an insulating layer on a surface of a first semiconductor wafer. The step (b) is to bond the insulating layer on the first semiconductor wafer to the surface of a second semiconductor wafer so that the same crystal orientations of the surfaces of the first and second semiconductor wafers are displaced at a predetermined angle with respect to each other. The step (c) is to thin the first semiconductor wafer after bonding to form an SOI (Semiconductor On Insulator) substrate with the second semiconductor wafer as a supporting substrate, the insulating layer as a first buried insulating layer, and a remainder of the first semiconductor wafer as a first SOI layer. The step (d) is to, using photolithographic and etching techniques, remove part of the first SOI layer and the first buried insulating layer to expose the supporting substrate. The step (e) is to, using an epitaxial growth technique, form a semiconductor layer in the exposed area of the supporting substrate. The step (f) is to, using a SIMOX (Separation by IMplanted OXygen) technique, form a second buried insulating layer in the semiconductor layer so that a surface-side portion of the semiconductor layer above the second buried insulating layer is to be a second SOI layer.

The above semiconductor device manufacturing method includes the step of bonding the insulating layer on the first semiconductor wafer to the second semiconductor wafer so that the same crystal orientations of the surfaces of the first and second semiconductor wafers are displaced at a predetermined angle with respect to each other; the step of forming the semiconductor layer; and the step of, using the SIMOX technique, forming the second buried insulating layer in the semiconductor layer so that the surface-side portion of the semiconductor layer above the second buried insulating layer is to be the second SOI layer. Thus, the surface of the second SOI layer formed by epitaxial growth is in the same crystal plane as the surface of the second semiconductor wafer, but the surface of the first SOI layer as the first semiconductor wafer is in a different crystal plane. That is, the first and second SOI layers can have different crystal orientations along a predetermined direction. Accordingly, it is possible to manufacture the semiconductor device according to the first aspect.

According to a third aspect of the present invention, the semiconductor device manufacturing method includes the following steps (a) to (e). The step (a) is to bond first and second semiconductor wafers together so that the same crystal orientations of the surfaces of the first and second semiconductor wafers are displaced at a predetermined angle with respect to each other. The step (b) is to thin the first semiconductor wafer after bonding to form a bulk substrate with the second semiconductor wafer as a supporting substrate and a remainder of the first semiconductor wafer as a first semiconductor layer. The step (c) is to, using photolithographic and etching techniques, remove part of the first semiconductor layer to expose the supporting substrate. The step (d) is to, using an epitaxial growth technique, form a second semiconductor layer in the exposed area of the supporting substrate. The step (e) is to, using a SIMOX (Separation by IMplanted OXygen) technique, form first and second buried insulating layers in the first and second semiconductor layers, respectively, so that a surface-side portion of the first semiconductor layer above the first buried insulating layer is to be a first SOI (Semiconductor On Insulator) layer and a surface-side portion of the second semiconductor layer above the second buried insulating layer is to be a second SOI layer.

The above semiconductor device manufacturing method includes the step of bonding the first and second wafers together so that the same crystal orientations of the surfaces of the first and second semiconductor wafers are displaced at a predetermined angle with respect to each other; the step of forming the second semiconductor layer; and the step of, using the SIMOX technique, forming the first and second buried insulating layers in the first and second semiconductor layers, respectively, so that the surface-side portion of the first semiconductor layer above the first buried insulating layer is to be the first SOI layer and the surface-side portion of the second semiconductor layer above the second buried insulating layer is to be the second SOI layer. Thus, the surface of the second SOI layer formed by epitaxial growth is in the same crystal plane as the surface of the second semiconductor wafer, but the surface of the first SOI layer as the first semiconductor wafer is in a different crystal plane. That is, the first and second SOI layers can have different crystal orientations along a predetermined direction. Accordingly, it is possible to manufacture the semiconductor device according to the first aspect.

According to a fourth aspect of the present invention, the semiconductor device manufacturing method includes the following steps (a) to (f). The step (a) is to bond first and second semiconductor wafers together so that the same crystal orientations of the surfaces of the first and second semiconductor wafers are displaced at a predetermined angle with respect to each other. The step (b) is to thin the first semiconductor wafer after bonding to form a bulk substrate with the second semiconductor wafer as a first supporting substrate and a remainder of the first semiconductor wafer as a first semiconductor layer. The step (c) is to, using photolithographic and etching techniques, remove part of the first semiconductor layer to expose the first supporting substrate. The step (d) is to, using an epitaxial growth technique, form a second semiconductor layer in the exposed area of the first supporting substrate. The step (e) is to bond the first and second semiconductor layers on the surface of the bulk substrate to the surface of a third semiconductor wafer with an insulating layer formed thereon. The step (f) is to thin the bulk substrate after bonding to form an SOI substrate with the third semiconductor wafer as a second supporting substrate, the first and second semiconductor layers as first and second SOI (Semiconductor On Insulator) layers, and the insulating layer as a buried insulating layer.

The above semiconductor device manufacturing method includes the step of bonding the first and second semiconductor wafers together so that the same crystal orientations of the surfaces of the first and second semiconductor wafers are displaced at a predetermined angle with respect to each other; the step of forming the second semiconductor layer; and the step of bonding the first and second semiconductor layers on the surface of the bulk substrate to the surface of the third semiconductor wafer with the insulating layer formed thereon, thereby to form an SOI substrate with the first and second semiconductor layers as the first and second SOI layers and the insulating layer as the buried insulating layer. Thus, the surface of the second SOI layer formed by epitaxial growth are in the same crystal plane as the surface of the second semiconductor wafer, but the surface of the first SOI layer as the first semiconductor wafer is in a different crystal plane. That is, the first and second SOI layers can have different crystal orientations along a predetermined direction. Accordingly, it is possible to manufacture the semiconductor device according to the first aspect.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 13 are cross-sectional views showing the process steps of a semiconductor device manufacturing method according to a first preferred embodiment;

FIG. 14 is a cross-sectional view of a semiconductor device according to the first preferred embodiment;

FIG. 15 shows the drain-source current and voltage characteristics of MOS transistors;

FIG. 16 is a cross-sectional view of another semiconductor device according to the first preferred embodiment;

FIG. 17 is a cross-sectional view showing one of the process steps of another semiconductor device manufacturing method according to the first preferred embodiment;

FIG. 18 is a cross-sectional view of still another semiconductor device according to the first preferred embodiment;

FIG. 19 is a cross-sectional view showing one of the process steps of still another semiconductor device manufacturing method according to the first preferred embodiment;

FIG. 20 is a top view of still another semiconductor device according to the first preferred embodiment;

FIG. 21 is a cross-sectional view of still another semiconductor device according to the first preferred embodiment;

FIG. 22 shows the relationship between electron and hole mobility and crystal orientations;

FIGS. 23 to 34 are cross-sectional views showing the process steps of a semiconductor device manufacturing method according to a second preferred embodiment;

FIG. 35 is a cross-sectional view of a semiconductor device according to the second preferred embodiment; and

FIGS. 36 to 39 are cross-sectional views showing the process steps of a semiconductor device manufacturing method according to a third preferred embodiment.

### DESCRIPTION OF THE PREFERRED EMBODIMENTS

### First Preferred Embodiment

This preferred embodiment provides a semiconductor device and its manufacturing method, in which a buried oxide film is also provided in the area where an epitaxial growth layer is formed, using the SIMOX (Separation by IMplanted OXygen) technique.

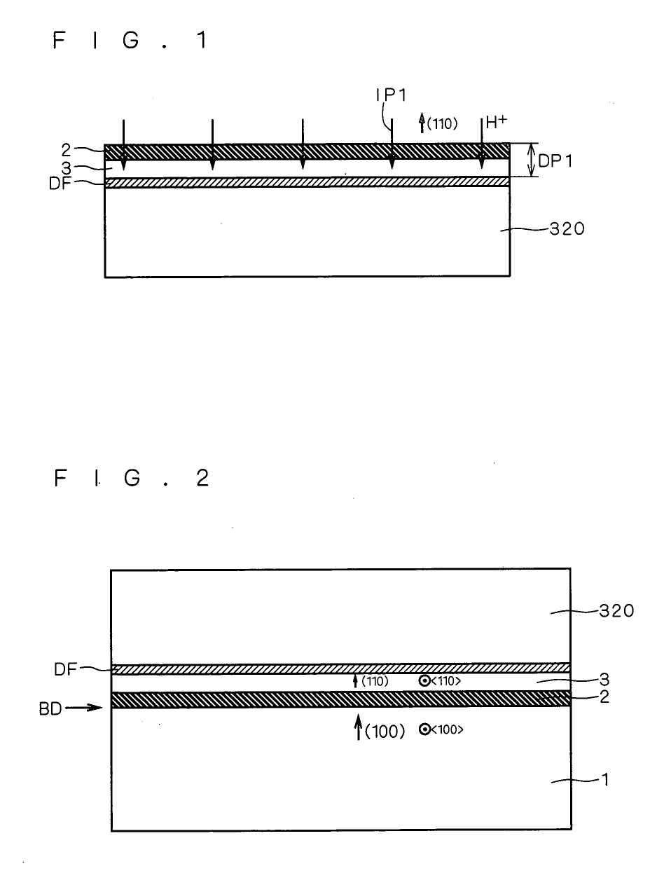

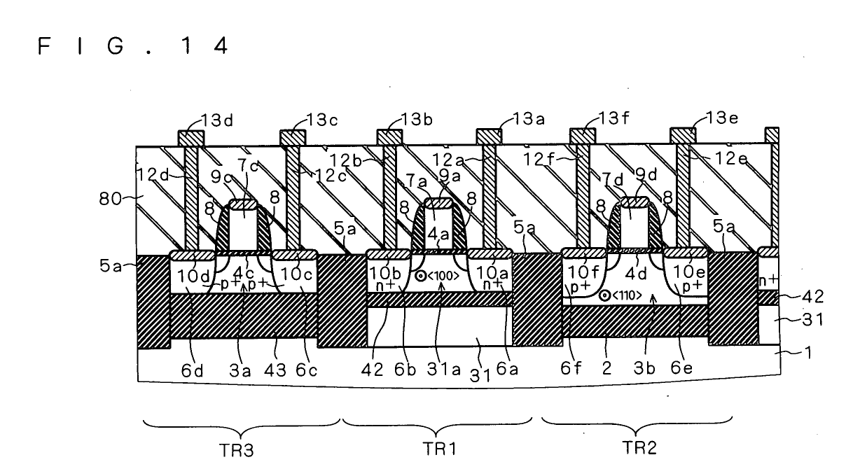

FIGS. 1 to 13 are cross-sectional views showing the process steps of a semiconductor device manufacturing method according to this preferred embodiment. FIG. 14 is a cross-sectional view of a semiconductor device according to this preferred embodiment. In semiconductor device manufacture according to this preferred embodiment, the so-called SMART CUT technology is used as an example of methods for forming SOI substrates.

As shown in FIG. 1, firstly, a semiconductor wafer 320 such as a silicon wafer is provided, on the surface of which an insulating layer 2 such as silicon oxide film is formed by CVD (Chemical Vapor Deposition), for example. The surface of the semiconductor wafer 320 is in a (110) crystal plane, so the semiconductor wafer 320 is a so-called (110) wafer. The up-pointing arrow and the number in the parenthesis, (110), next to the arrow in FIG. 1 indicate that the semiconductor wafer 320 is a (110) wafer (the same meaning applies to arrows and numbers in parentheses in the following drawings).

Then, a crystal defect layer DF is formed at a predetermined depth DP1 from the surface by hydrogen ion implantation IP1. A semiconductor layer 3 between the insulating layer 2 and the crystal defect layer DF is to be an SOI (Semiconductor On Insulator) layer after going through processes described later.

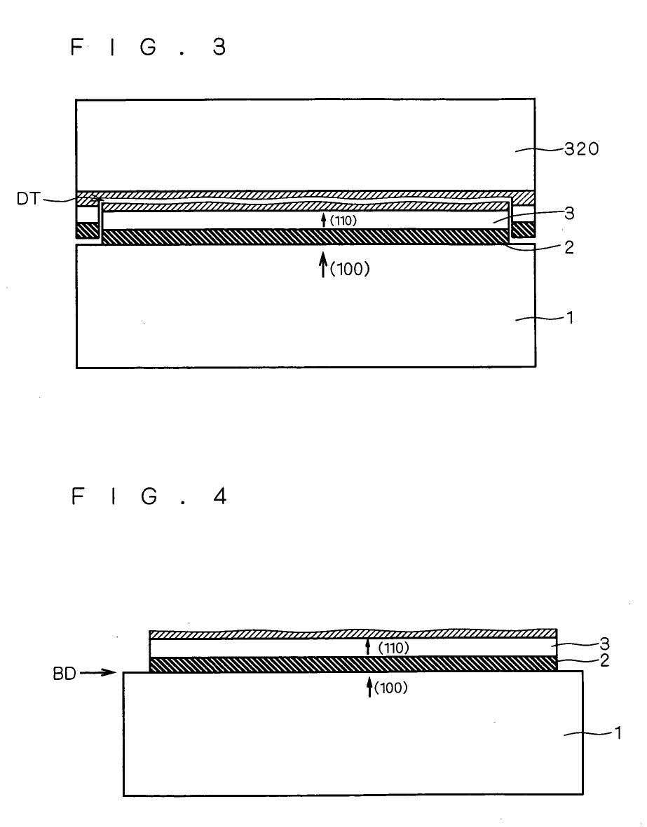

Then, as shown in FIG. 2, the insulating layer 2 on the semiconductor wafer 320 is bonded to the surface of a semiconductor wafer I such as a silicon wafer. The surface of the semiconductor wafer 1 is in a (100) crystal plane, so the semiconductor wafer 1 is a so-called (100) wafer. That is, the insulating layer 2 on the semiconductor wafer 320 with (110) surface orientation is bonded to the semiconductor wafer 1 with different (100) surface orientation.

In FIG. 2, the bonding surface is indicated by BD. Further, the double circles and the numbers in angle brackets, <110> and <100>, next to the double circles in FIG. 2 respectively indicate arrows and crystal orientations in a direction perpendicular to the plane of the drawing (the same meaning applies to double circles and numbers in angle brackets in the following drawings).

At this time, the semiconductor wafers 1 and 320 are bonded together so that the same <110> crystal orientations of the bonded surfaces of the semiconductor wafers 1 and 320 are displaced at a predetermined angle (e.g., 45 degrees) with respect to each other. By so doing, as shown in FIG. 2, the semiconductor layer 3 to be the SOI layer and the semiconductor wafer 1 to be a supporting substrate can have different crystal orientations along a direction perpendicular to one wafer section, the semiconductor layer 3 having a <110> crystal orientation and the semiconductor wafer 1 having a <100> crystal orientation.

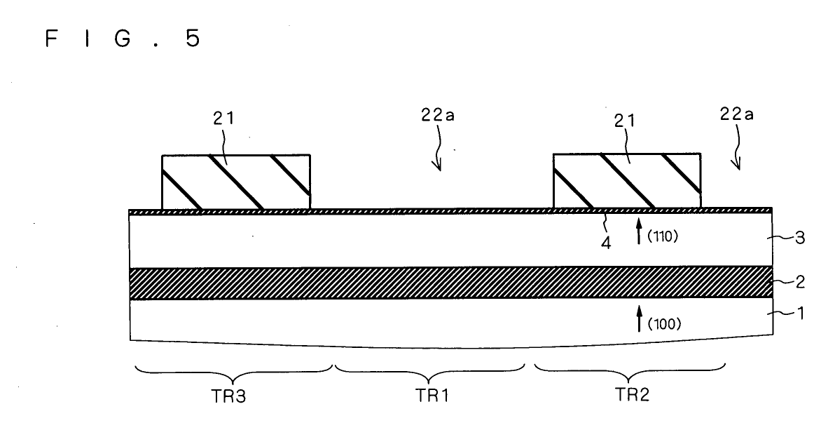

Then, the crystal defect layer DF is weakened by heat treatment, and the semiconductor wafer 320 is split at the crystal defect layer DF as shown in FIG. 3. At this time, the outer edge of the semiconductor wafer 320 is also removed because of weak bonding strength. In FIG. 3, the split surface is indicated by DT.

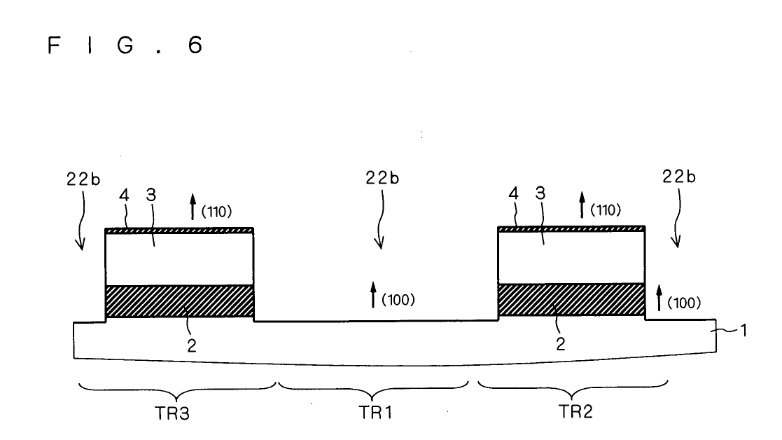

In the condition of FIG. 4, additional heat treatment is applied to increase the bonding strength between the insulating layer 2 and the semiconductor wafer 1, and the surface of the semiconductor layer 3 is lightly polished to remove the remaining crystal defect layer. This produces an SOI substrate. That is, thinning the semiconductor wafer 320 after bonding produces an SOI substrate with the semiconductor wafer 1 as a supporting substrate, the insulating layer 2 as a buried insulating layer, and the semiconductor layer 3 or a remainder of the semiconductor wafer 320 as an SOI layer. From this, the semiconductor wafer 1, the insulating layer 2, and the semiconductor layer 3 are hereinafter referred to as the “supporting substrate 1”, the “buried insulating layer 2”, and the “SOI layer 3,” respectively. A total film thickness of the buried insulating layer 2 and the SOI layer 3 should be, for example, between 100 and 2000 nm.

While in the present example the SMART CUT technology is used as an example of the methods for forming SOI substrates, other methods may be used instead. For example, bonded semiconductor wafers may be thinned by CMP (Chemical Mechanical Polishing) to form an SOI substrate.

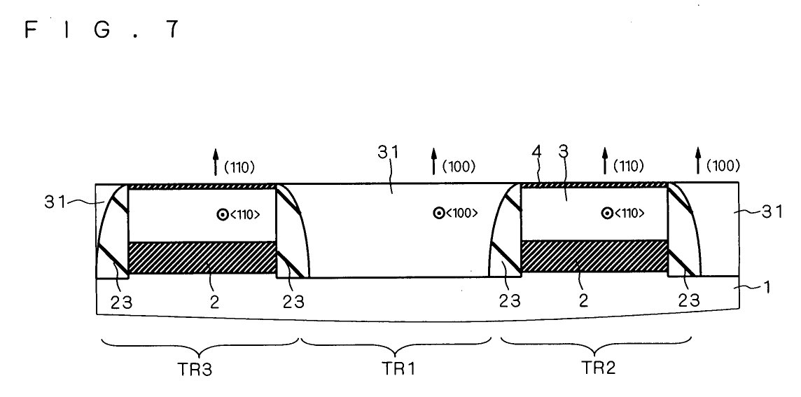

Then, as shown in FIG. 5, an insulating film 4 is formed on the SOI substrate. The insulating film 4 is made of, for example, thermal oxide film or TEOS oxide film and has a thickness of, for example, approximately 5 to 40 nm. Then, a mask layer 21 used in the formation of an epitaxial growth area is formed on the insulating film 4. The mask layer 21 has a thickness of, for example, approximately 50 to 300 nm and is made of, for example, silicon nitride film. Silicon nitride film can be formed using techniques such as LPCVD (Low Pressure Chemical Vapor Deposition) and plasma CVD.

The mask layer 21 is then patterned using photolithographic and etching techniques to form a pattern 22a for formation of the epitaxial growth area. More specifically, a photoresist is formed on the mask layer 21 and then patterned. Thereafter, using the photoresist as a mask, the mask layer 21 is etched with RIE (Reactive Ion Etching) and ECR (Electron Cyclotron Resonance) devices. The photoresist is then removed using an ashing device and a mixed solution of sulfuric acid and hydrogen peroxide solution.

In FIG. 5, TR1 indicates an area where an n-channel MOS transistor is formed, and TR2 and TR3 indicate areas where p-channel MOS transistors are formed.

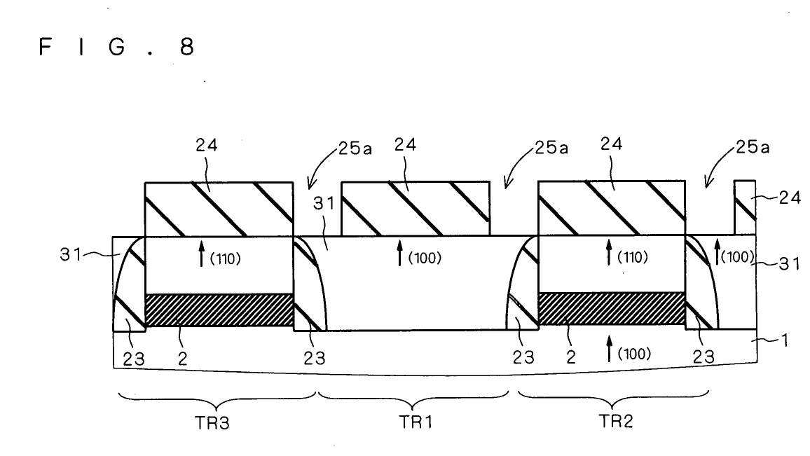

The insulating film 4, the SOI layer 3, and the buried insulating layer 2 are then etched using RIE and ECR devices to form trenches 22b for formation of the epitaxial growth area (FIG. 6). That is, using photolithographic and etching techniques, the SOI layer 3 and the buried insulating layer 2 are partly removed to expose the supporting substrate 1.

Then, a sidewall material such as silicon nitride film is formed to sufficiently fill in the trenches 22b (not shown). The sidewall material is then etched back to form sidewalls 23 on the side faces of the trenches 22b as shown in FIG. 7.

Following this, using epitaxial growth techniques, a semiconductor layer 31 such as a silicon layer is formed on the exposed area of the supporting substrate 1 in the trenches 22b. The surface-side portion of the semiconductor layer 31 formed by this epitaxial growth is to be an SOI layer after going through processes described later.

The surface of the semiconductor layer 31 is in the same (100) crystal plane as the surface of the semiconductor wafer 1, but the surface of the SOI layer 3 which was the semiconductor wafer 320 is in a different (110) crystal plane. That is, the SOI layer 3 and the semiconductor layer 31 can have different crystal orientations along a direction perpendicular to one wafer section, the SOT layer 3 having a <110> crystal orientation and the semiconductor layer 31 having a <100> crystal orientation.

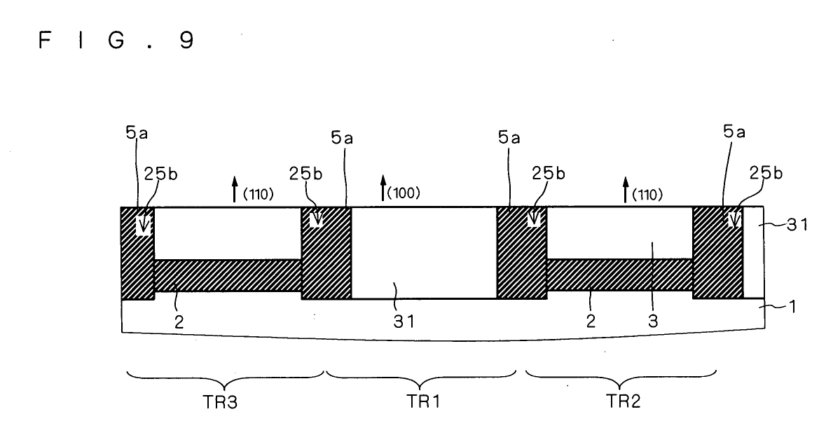

The insulating film 4 is then removed for example by etch back, and a mask layer 24 is formed, in which a pattern 25a for formation of a complete isolation insulating film is formed (FIG. 8). This mask layer 24 is made of, for example, a photoresist.

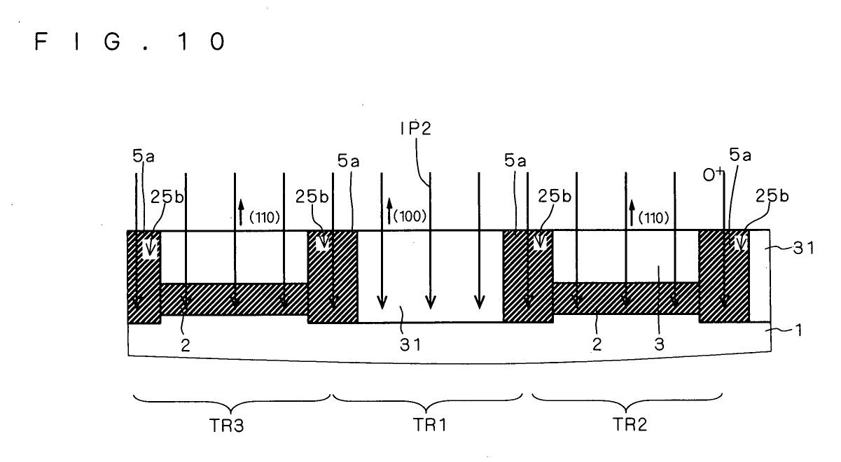

Then, using RIE and ECR devices, the semiconductor layer 31 and the sidewalls 23 are etched to form trenches 25b for formation of the complete isolation insulating film. Then, an isolation-film material such as silicon oxide film is formed to sufficiently fill in the trenches 25b, and is etched back to form a complete isolation insulating film 5a in the trenches 25b as shown in FIG. 9.

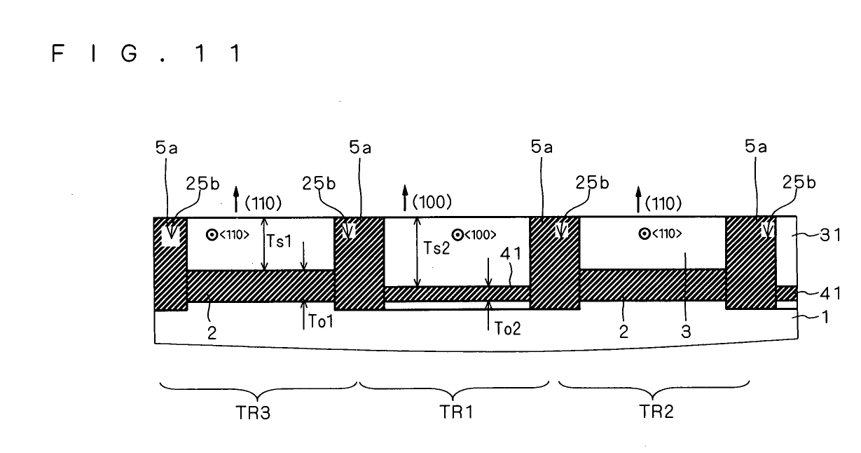

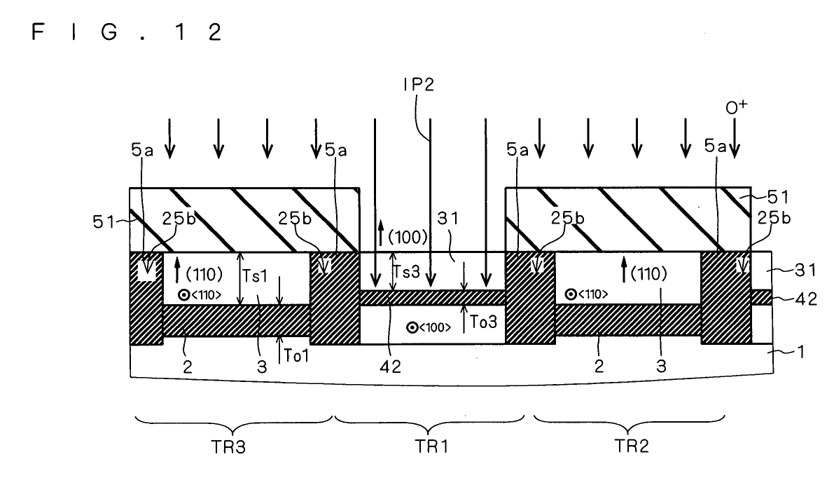

Following this, using the SIMOX technique, oxygen ion implantation IP2 is performed on the SOI substrate (FIG. 10). The implantation should be done, for example, at a dose of approximately 1.0×10¹⁷[cm⁻²]. Then, a buried insulating layer 41 is formed in the semiconductor layer 31 by high-temperature annealing (FIG. 11).

The surface-side portion of the semiconductor layer 31 above the buried insulating layer 41 is to be an SOI layer where devices such as MOS transistors are formed. Hereinafter, this surface-side portion above the buried insulating layer 41 is referred to as the “SOI layer 31.”

In FIG. 11, by controlling the ion implant dose, the thickness To1 of the buried insulating layer 2 and the thickness To2 of the buried insulating layer 41 are made different. Further, by controlling the location of the peak concentration of implanted ions, the bottom surfaces of the buried insulating layers 2 and 41 are approximately aligned with each other. Thus, the SOI layers 3 and 31 have different thicknesses Ts1 and Ts2, respectively.

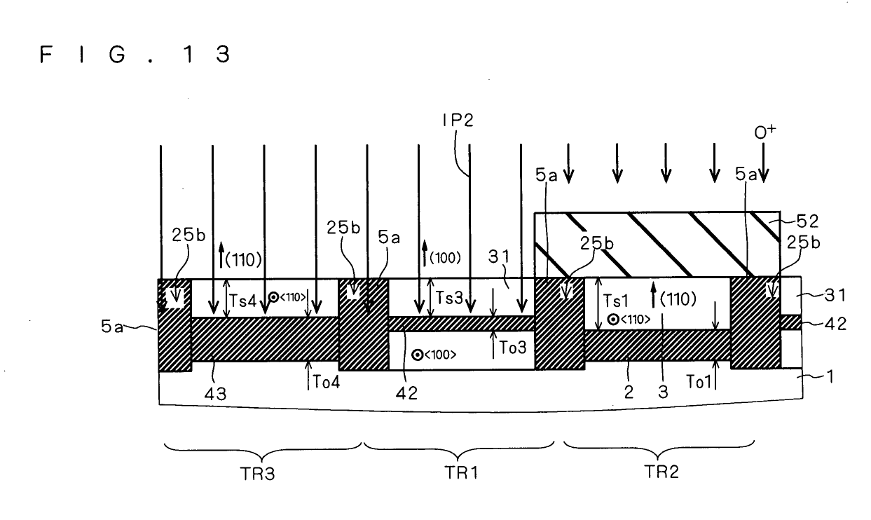

In the case of FIG. 10, the ion implantation IP2 is performed on the entire surface of the SOI substrate. As an alternative, as shown in FIG. 12, after an ion implantation stopping film (e.g., silicon nitride film) 51 is selectively formed on the surface of the SOI substrate in the regions TR2 and TR3, the ion implantation IP2 may be performed to form a buried insulating layer 42. In FIG. 12, the ion implantation IP2 is performed only on the region TR1, and the bottom surface of the buried insulating layer 42 and the top surface of the buried insulating layer 2 are approximately aligned with each other. Thus, the thickness Ts3 of the SOI layer 31 can be smaller than the thickness Ts1 of the SOI layer 3.

As another alternative, as shown in FIG. 13, after an ion implantation stopping film 52 is selectively formed on the surface of the SOI substrate in the region TR2, the ion implantation IP2 may be performed to form the buried insulating layer 42. In FIG. 13, the ion implantation IP2 is performed only on the regions TR1 and TR3, and the bottom surface of the buried insulating layer 42 and the top surface of the buried insulation layer 2 are approximately aligned with each other. Thus, the thickness Ts3 of the SOI layer 31 can be smaller than the thickness Ts1 of the SOI layer 3. Further, in the region TR3, a buried insulating layer 43 with a thickness To4 is formed of the buried insulating layer 2 with the thickness To1 and the buried insulating layer 42 with the thickness To3. Thus, the thickness Ts4 of the SOI layer 3 in the region TR3 is smaller than the thickness Ts1 of the SOI layer 3 in the region TR2 and is approximately the same as the thickness Ts3 of the SOI layer 31 in the region TR1.

Thereafter, as shown in FIG. 14, other components are formed, namely, gate insulating films 4a, 4c, and 4d such as silicon oxide film, gate electrodes 7a, 7c, and 7d such as polycrystalline silicon, sidewalls 8 such as silicon nitride film, body layers 3a, 31a, and 3b, source/drain regions 6a to 6f including extension regions, silicide layers 9a, 9c, 9d, and 10a to 10f, an interlayer insulation film 80 such as silicon oxide film, contact plugs 12a to 12f, and interconnect lines 13a to 13f.

In the aforementioned manufacturing method, the insulating layer 2 on the semiconductor wafer 320 is bonded to the semiconductor wafer 1 so that the same <110> crystal orientations of the surfaces of the semiconductor wafers 1 and 320 are displaced at a predetermined angle with respect to each other, and the buried insulating layer 41 or 42 is formed in the semiconductor layer 31, using the SIMOX technique. Then, the surface-side portion of the semiconductor layer 31 above the buried insulating layer 41 or 42 is taken as the SOI layer 31.

Accordingly, the surface of the SOI layer 31 formed by epitaxial growth is in the same crystal plane as the surface of the semiconductor wafer 1, but the surface of the SOI layer 3 which was the semiconductor wafer 320 is in a different crystal plane. That is, in FIG. 14, the body layers 3a and 3b of the SOI layer and the body layer 31a of the SOI layer are in different crystal orientations, the body layers 3a and 3b having a <110> crystal orientation and the body layer 31a having a <100> crystal orientation. Thus, in the region TR1, n-channel MOS transistors with a channel direction of <100> crystal orientation can be formed, and in the regions TR2 and TR3, p-channel MOS transistors with a channel direction of <110> crystal orientation can be formed.

Further, it is also possible to form the buried insulating layers 42 and 43 using the SIMOX technique, after selective formation of the ion implantation stopping films 51 and 52 on the SOI substrate surface. Thus, each of the buried insulating layers 2, 42, and 43 can have a different thickness.

The semiconductor device according to this preferred embodiment includes the buried insulating layers 2, 42, and 43 provided on the surface of the supporting substrate 1 in the regions TR1, TR2, and TR3, respectively; and the body layers 3b, 31a, and 3a as the SOI layer provided on the buried insulating layers 2, 42, and 43, respectively. The body layer 31a of the SOI layer and the body layers 3a and 3b of the SOI layer have different crystal orientations along a direction perpendicular to one wafer section, the body layer 31a having a <100> crystal orientation and the body layers 3a and 3b having a <110> crystal orientation.

Accordingly, it is possible to mix a plurality of different crystal orientations in the SOI substrate surface and to control increase of leakage current into the substrate and increase in power consumption in each area by the buried insulating layers 2, 42, and 43.

Further, the buried insulating layers 2, 42, and 43 can have different thicknesses. Accordingly, in the area of the thin buried insulating layer 42, heat generated in transistors formed on the body layer 31 a of the SOI layer on the buried insulating layer 42 can be diffused and released to the supporting substrate 1. Such transistors on thin buried insulating layers are suitable for analog circuits. On the other hand, in the area of the thick buried insulating layers 2 and 43, electrostatic capacity between the supporting substrate 1 under the buried insulating layers 2 and 43 and the body layers 3a and 3b of the SOI layer on the buried insulating layers 2 and 43 can be reduced to a smaller value, so that high-speed and low-power devices can be formed on the body layers 3a and 3b of the SOI layer. Such transistors on thick buried insulating layers are suitable for logic circuits.

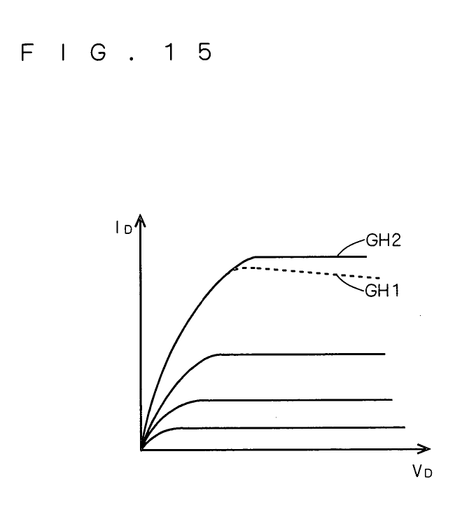

FIG. 15 is a diagram showing the general characteristics of the drain-source current ID and voltage VD of n-channel MOS transistors formed on the SOI substrate. The curve GH1 indicates the case of thick buried insulating layers formed under n-channel MOS transistors, and the curve GH2 indicates the case of thin buried insulating layers formed under n-channel MOS transistors.

In a high voltage (V_{D}) area, the current I_{D} on the curve GH2 is higher than that on the curve GH1. This indicates that thin buried insulating layers are better in controlling reduction in current I_{D} in the high voltage (V_{D}) area and superior in signal transmission capability.

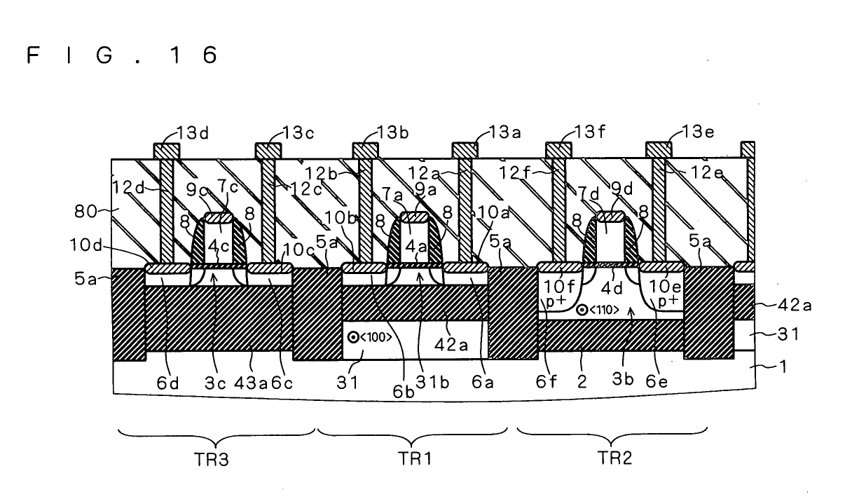

Further, as shown in FIG. 16, the buried insulating layers 42 and 43 in FIG. 14 may be increased in thickness to be buried insulating layers 42a and 43a, respectively. In this case, since the body layers 3c and 31b of the SOI layer become thin, transistors formed in the regions TR1 and TR3 are to be of the full depletion type. On the other hand, transistors formed in the region TR2 are of the partial depletion type since the body layer 3b as the SOI layer is still thick.

That is, according to the present invention, since the body layers 3c, 3b, and 31b of the SOI layer can be made in different thicknesses, full depletion type transistors can be formed in the thin area of the SOI layer. Besides, it is also possible in the thin area of the SOI layer to control the short channel effect of transistors and thereby to increase the resistance to roll-off (the independence of the threshold voltage from the gate length). Further, in the thick area of the SOI layer, partial depletion type transistors can be formed.

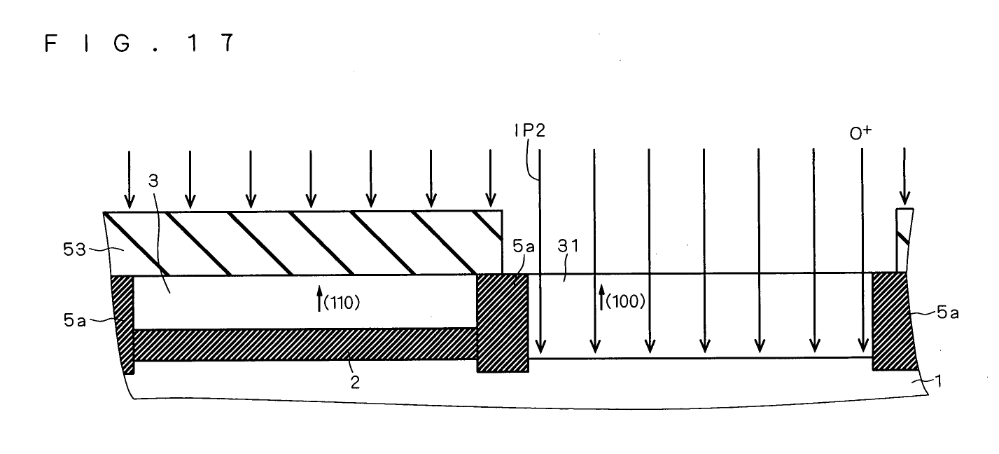

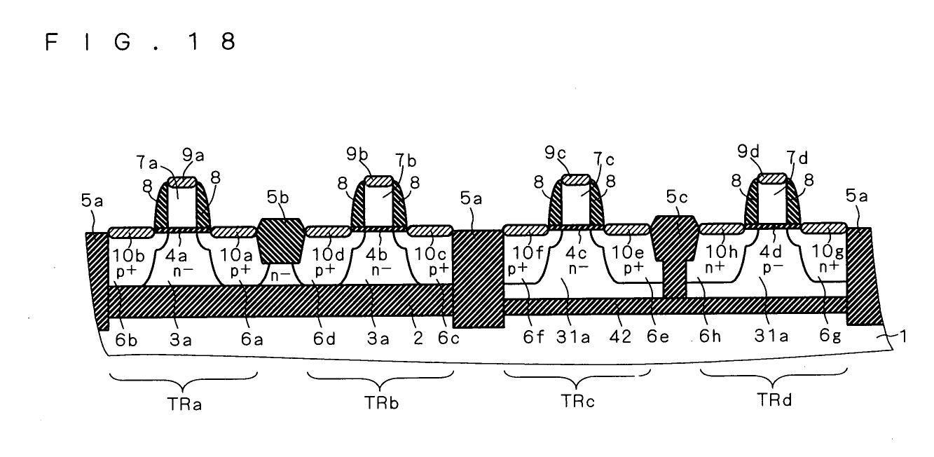

As an alternative, the area where complete element isolation film is formed and the area where partial element isolation film is formed may be mixed. FIGS. 17 and 18 are diagrams for explaining this.

As shown in FIG. 17, in similar manner as in FIG. 12, the ion implantation IP2 is performed through an ion implantation stopping film 53, using the SIMOX technique. Thereby the buried insulating layer 42 is also formed in the semiconductor layer 31, and then, as shown in FIG. 18, the gate insulating films 4a to 4d, the gate electrodes 7a to 7d, the sidewalls 8, the body layers 3a and 31 a, the source/drain regions 6a to 6h, the silicide layers 9a to 9d and 10a to 10h, a partial element isolation film 5b such as silicon oxide film, and a complete element isolation film 5c such as silicon oxide film are formed in similar manner as in FIG. 14.

At this time, the partial element isolation film 5b is formed in the SOI layer at the boundary between regions TRa and TRb not to reach the buried insulating layer 2. On the other hand, the complete element isolation film 5c is formed in the SOI layer at the boundary between regions TRc and TRd to reach the buried insulating layer 42.

By in this way mixing the complete element isolation film 5c and the partial element isolation film 5b, the complete element isolation film 5c can completely isolate a plurality of devices (respective transistors in the regions TRc and TRd) formed on the surface of the SOI layer as well as the SOI layer under those devices, and the partial element isolation film 5b can provide partial isolation between a plurality of devices (respective transistors in the regions TRa and TRb) formed on the surface of the SOI layer while providing electrical continuity therebetween in the deepest part of the SOI layer.

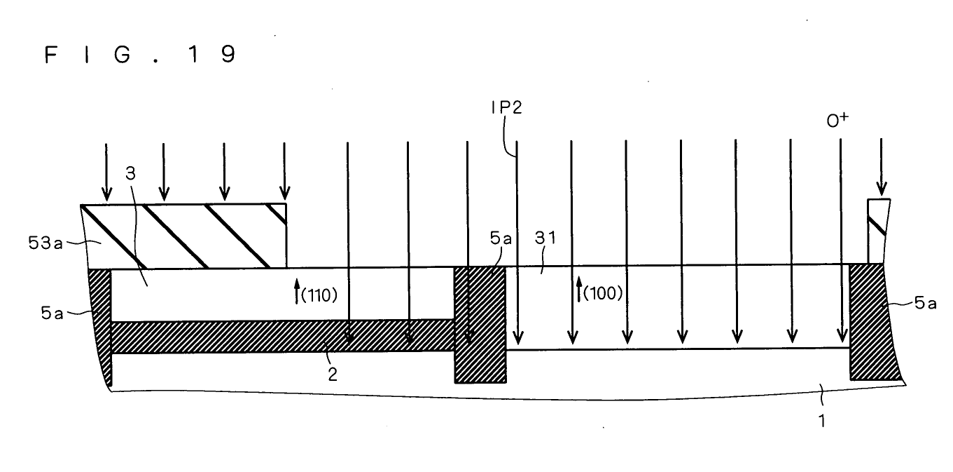

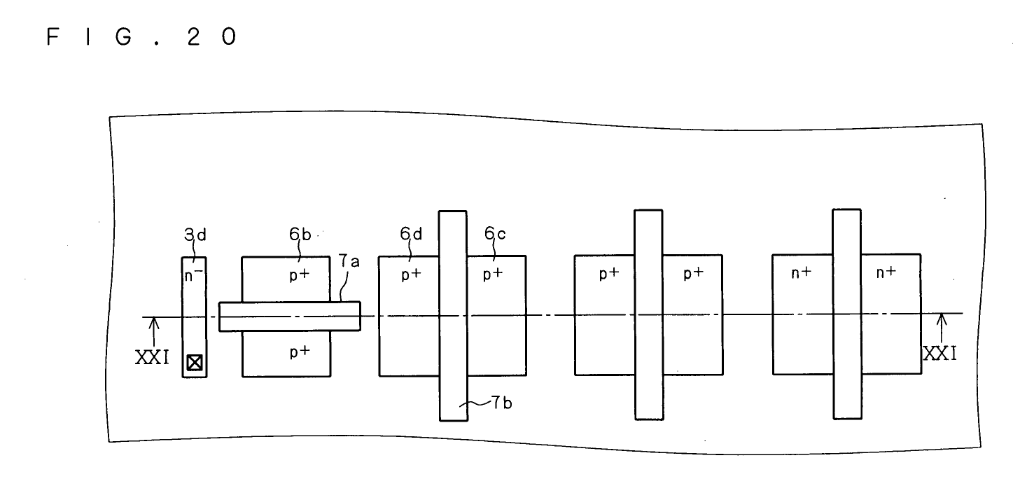

Further, the buried insulating layer in each area divided by the complete isolation insulating film 5a may have a different thickness. FIGS. 19 to 21 are diagrams for explaining this. FIG. 21 is a cross-sectional view taken along the line XXI-XXI of FIG. 20.

As shown in FIG. 19, in similar manner as in FIG. 12, the ion implantation IP2 is performed through an ion implantation stopping film 53a, using the SIMOX technique. Here, the ion implantation stopping film 53a covers not all but only part of the SOI layer 3.

Thereby, as shown in FIG. 21, not only the buried insulating layer 42 is formed in the SOI layer 31, but also part of the buried insulating layer 2 is thickened to form a buried insulating layer 2b. Thereafter, the gate insulating films 4a to 4d, the gate electrodes 7a to 7d, the sidewalls 8, the body layers 3a, 3d, and 31a, the source/drain regions 6a to 6h, the silicide layers 9a to 9d and 10a to 10h (10a and 10b are not shown in FIGS. 20 and 21), the partial element isolation film 5b such as silicon oxide film, and the complete element isolation film 5c such as silicon oxide film are formed in similar manner as in FIG. 14.

We have so far described the mixing of buried insulating layers (2, 42, 43) of different thicknesses as in FIG. 14, the mixing of full depletion type transistors (in the regions TR1 and TR3) and partial depletion type transistors (in the region TR2) as in FIG. 16, the mixing of the complete element isolation film 5c and the partial element isolation film 5b as in FIG. 18, the mixing of the thin and thick buried insulating layers 2a and 2b in each area divided by the complete isolation insulating film 5a as in FIG. 21, all of which mixing may further be combined in any manner. Also, a bulk structure with no buried insulating layer may be combined.

While in the above example, n-channel MOS transistors with a channel direction of <100> crystal orientation are formed in the region TR1, and the p-channel MOS transistors with a channel direction of <110> crystal orientation are formed in the regions TR2 and TR3, other crystal orientations may be adopted instead.

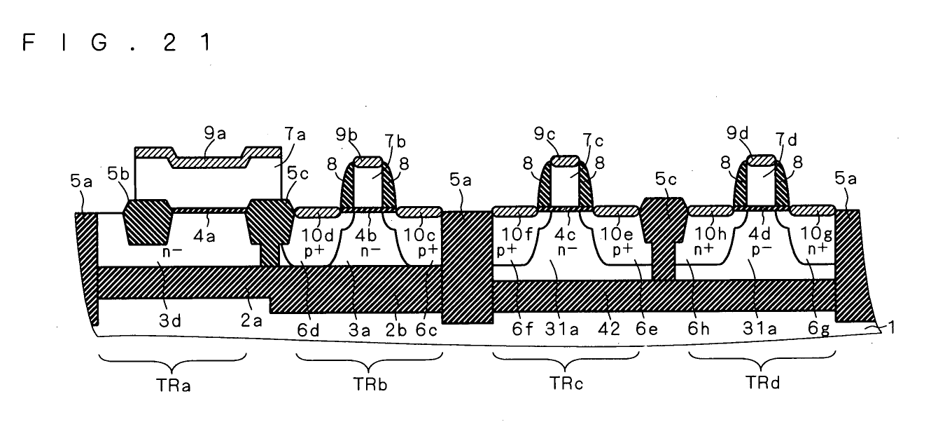

FIG. 22 shows the relationship between electron and hole mobility μFE and crystal orientations (angles from the (011) crystal plane). A desired channel crystal orientation should be selected to suit the characteristics of transistors required to be produced.

### Second Preferred Embodiment

This preferred embodiment is a modification of the semiconductor device manufacturing method according to the first preferred embodiment, in which after two bulk wafers are bonded together to mix a plurality of different crystal orientations in the surface of a bulk substrate, buried insulating layers are formed to obtain an SOI substrate.

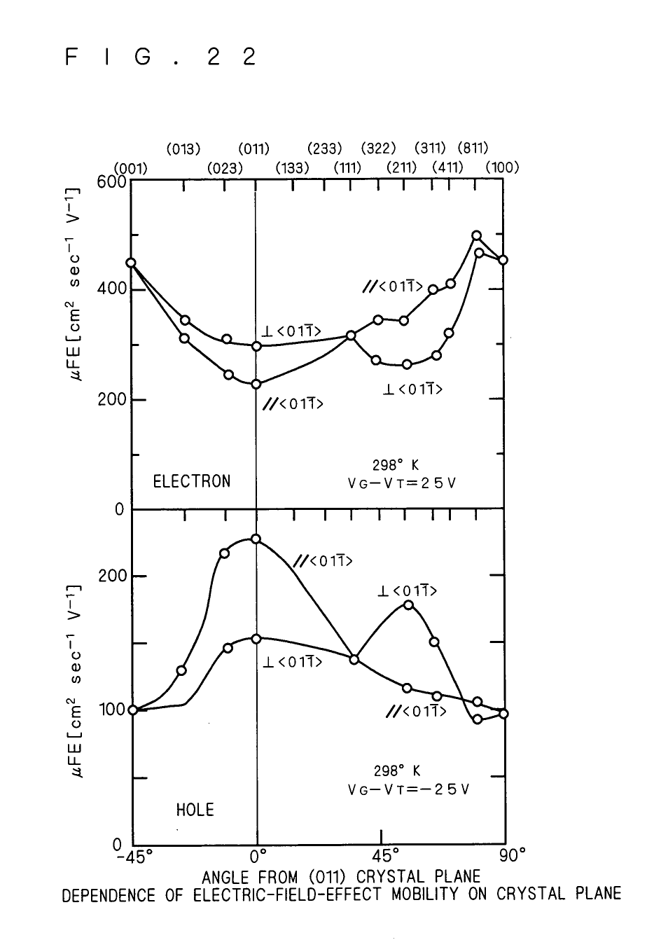

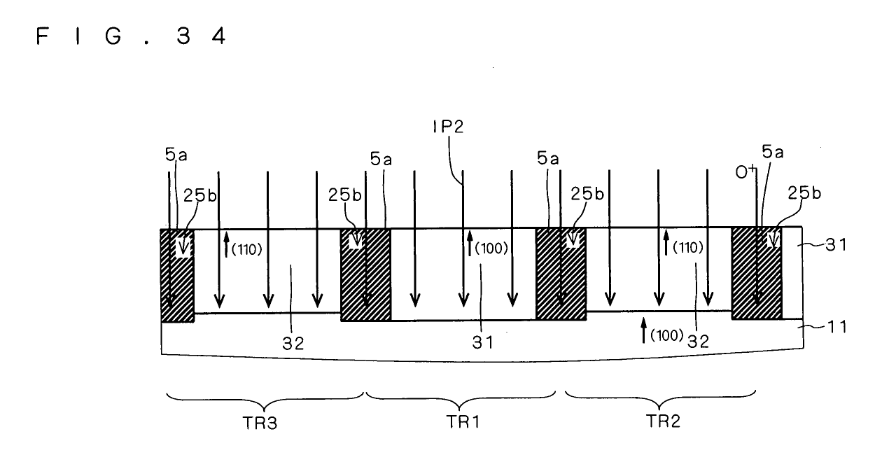

FIGS. 23 to 34 are cross-sectional views showing the process steps of a semiconductor device manufacturing method according to this preferred embodiment. FIG. 35 is a cross-sectional view of a semiconductor device according to this preferred embodiment. Also in semiconductor device manufacture according to this preferred embodiment, the so-called SMART CUT technology is used as an example of methods for forming bonded substrates.

As shown in FIG. 23, firstly, the semiconductor wafer 320 such as a (110) silicon wafer is prepared, in which the crystal defect layer DF is formed at the predetermined depth DP1 (e.g., 100 to 2000 nm) from the surface by hydrogen ion implantation IP1. A semiconductor layer 32 between the surface and the crystal defect layer DF is to be an SOI layer after going through processes described later.

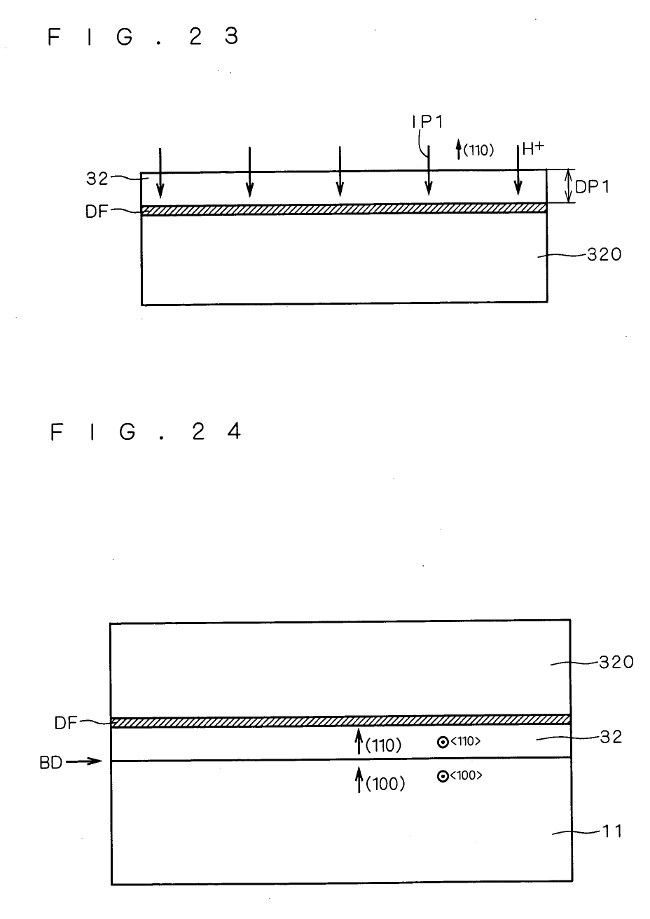

Then, as shown in FIG. 24, the surface of the semiconductor wafer 320 is bonded to the surface of a semiconductor wafer 11 such as a (100) silicon wafer. At this time, the semiconductor wafers 11 and 320 are bonded together so that the same <110> crystal orientations of the bonded surfaces of the semiconductor wafers 11 and 320 are displaced at a predetermined angle (e.g., 45 degrees) with respect to each other. By so doing, as shown in FIG. 24, the semiconductor layer 32 to be the SOI layer and the semiconductor wafer 11 to be a supporting substrate can have different crystal orientations along a direction perpendicular to one wafer section, the semiconductor layer 32 having a <110> crystal orientation and the semiconductor wafer 11 having a <100> crystal orientation.

Since, unlike in the first preferred embodiment, the semiconductor wafer 11 has no insulating layer formed thereon, the semiconductor wafers 11 and 320 are both bulk wafers.

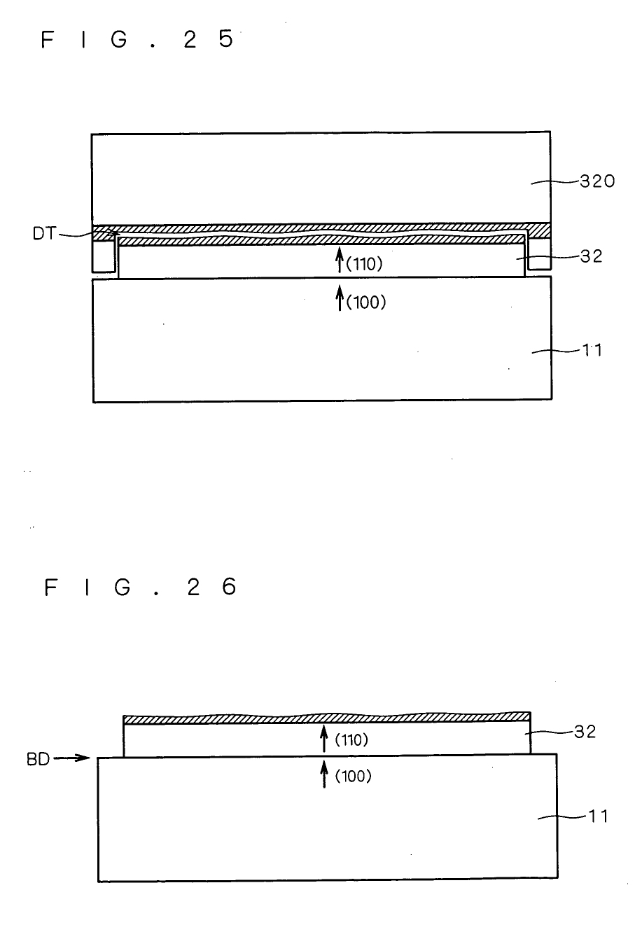

Then, the crystal defect layer DF is weakened by heat treatment, and the semiconductor wafer 320 is split at the crystal defect layer DF as shown in FIG. 25. At this time, the outer edge of the semiconductor wafer 320 is also removed because of weak bonding strength. In FIG. 25, the split surface is indicated by DT.

In the condition of FIG. 26, additional heat treatment is applied to increase the bonding strength between the semiconductor wafers 11 and 320, and the surface of the semiconductor layer 32 is lightly polished to remove the remaining crystal defect layer. This produces a bulk substrate with the semiconductor wafer 11 as a supporting substrate and the semiconductor layer 32 having a different crystal orientation from the supporting substrate. Hereinafter, the semiconductor wafer 11 is referred to as the “supporting substrate 11.”

While in the present example the SMART CUT technology is used as an example of the methods for forming bulk substrates with the semiconductor layer 32 and the supporting substrate 11 having different crystal orientations, other methods may be used instead. For example, bonded semiconductor wafers may be thinned by CMP.

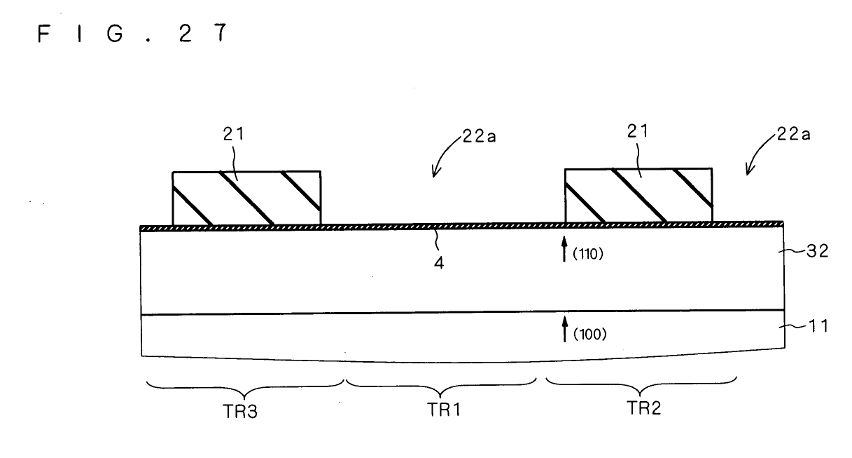

Then, as shown in FIG. 27, the insulating film 4 is formed on the bulk substrate. The insulating film 4 is made of, for example, thermal oxide film or TEOS oxide film and has a thickness of, for example, approximately 5 to 40 nm. Then, the mask layer 21 used in the formation of an epitaxial growth area is formed on the insulating film 4. The mask layer 21 has a thickness of, for example, approximately 50 to 300 nm and is made of, for example, silicon nitride film. Silicon nitride film can be formed using techniques such as LPCVD and plasma CVD.

The mask layer 21 is then patterned using photolithographic and etching techniques to form the pattern 22a for formation of the epitaxial growth area. More specifically, a photoresist is formed on the mask layer 21 and then patterned. Thereafter, using the photoresist as a mask, the mask layer 21 is etched with RIE and ECR devices. The photoresist is then removed using an ashing device and a mixed solution of sulfuric acid and hydrogen peroxide solution.

In FIG. 27, TR1 indicate an area where an n-channel MOS transistor is formed, and TR2 and TR3 indicate areas where p-channel MOS transistors are formed.

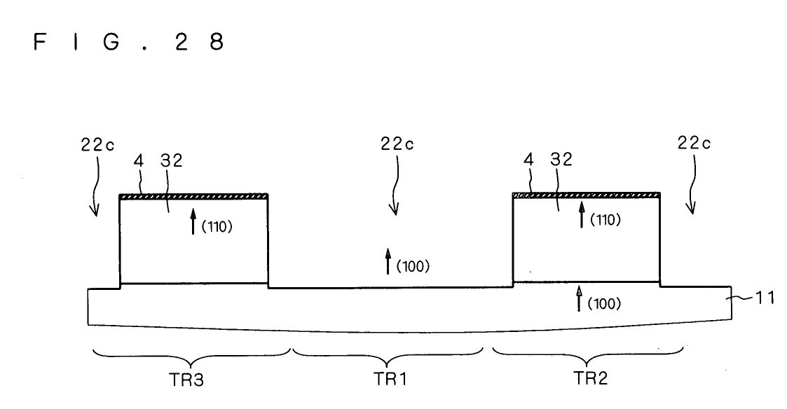

The insulating film 4 and the semiconductor layer 32 are then etched using RIE and ECR devices to form trenches 22c for formation of the epitaxial growth area (FIG. 28). That is, using photolithographic and etching techniques, the semiconductor layer 32 is partly removed to expose the supporting substrate 11.

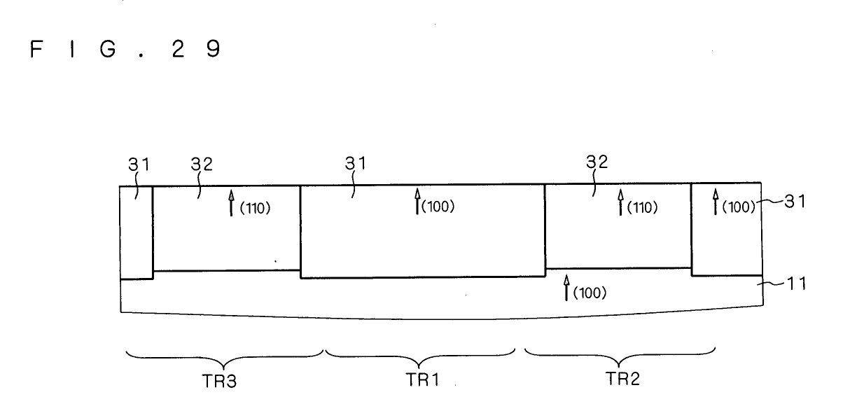

Following this, using epitaxial growth techniques, the semiconductor layer 31 such as a silicon layer is formed on the exposed area of the supporting substrate 11 in the trenches 22c. Then, the insulating film 4 is removed for example by etch back (FIG. 29). The surface-side portion of the semiconductor layer 32 formed by this epitaxial growth is to be an SOI layer after going through processes to be described later.

The surface of the semiconductor layer 31 is in the same (100) crystal plane as the surface of the semiconductor wafer 11, but the surface of the semiconductor layer 32 which was the semiconductor wafer 320 is in a different (110) crystal plane. That is, the semiconductor layers 32 and 31 can have different crystal orientations along a direction perpendicular to one wafer section, the semiconductor layer 32 having a <110> crystal orientation and the semiconductor layer 31 having a <100> crystal orientation.

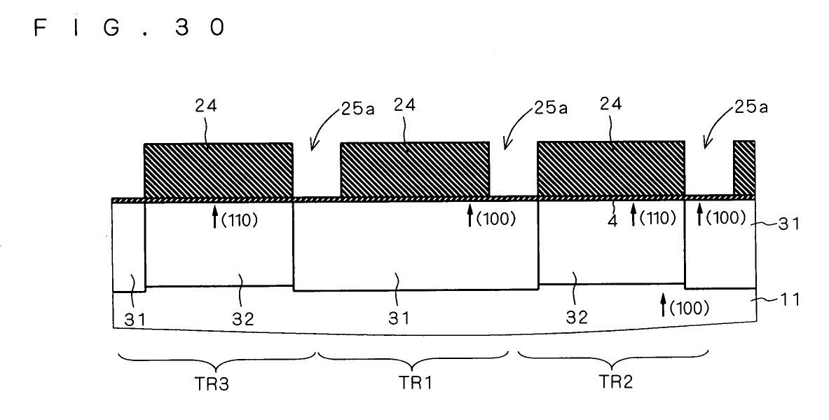

Thereafter, another insulating film 4 such as silicon oxide film is formed, and the mask layer 24 is formed in which the pattern 25a for formation of a complete isolation insulating film is formed (FIG. 30). This mask layer 24 is made of, for example, a photoresist.

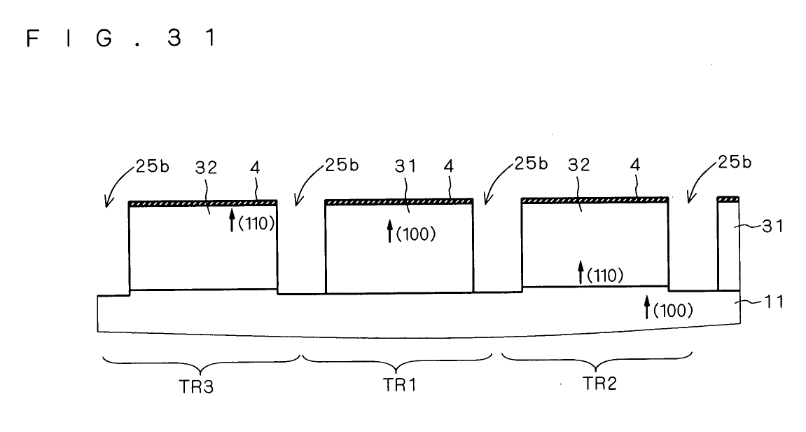

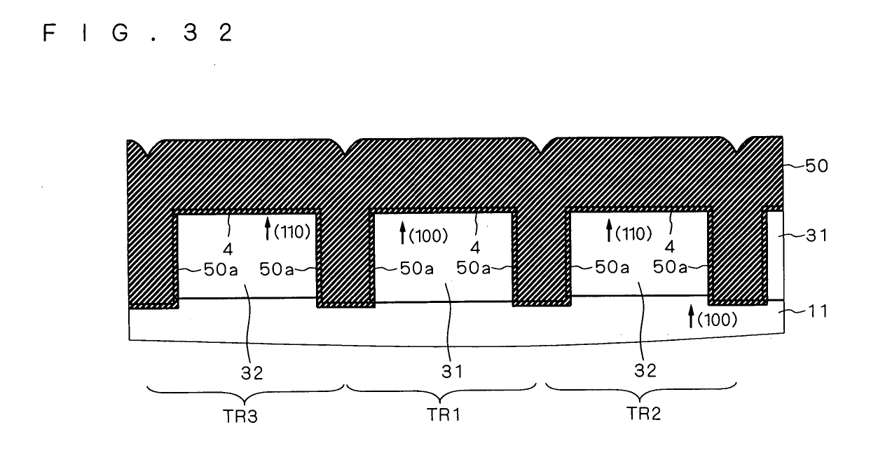

Then, using RIE and ECR devices, the semiconductor layer 31 is etched to form the trenches 25b for formation of the complete isolation insulating film (FIG. 31). After an inner-wall insulating film 50a such as silicon oxide film is formed by, for example, thermal oxidation, an isolation-film material 50 such as silicon oxide film is formed to sufficiently fill in the trenches 25b (FIG. 32).

The isolation-film material 50 is then etched back to form the complete isolation insulating film 5a within the trenches 25b as shown in FIG. 33.

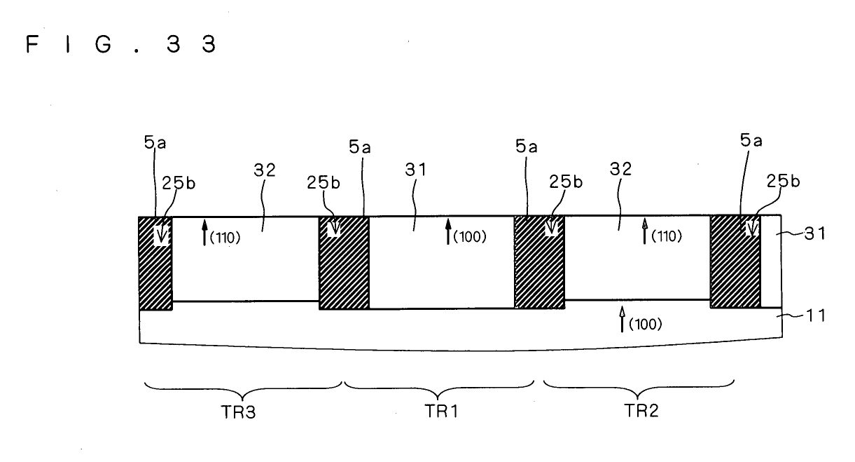

Following this, using the SIMOX technique, the oxygen ion implantation IP2 is performed on the SOI substrate (FIG. 34). The implantation should be done, for example at a dose of approximately 1.0×10¹⁷[cm⁻²]. Then, the buried insulating layer 2 is formed in the semiconductors layers 31 and 32 by high-temperature annealing (FIG. 35).

The surface-side portions of the semiconductor layers 31 and 32 above the buried insulating layer 2 are to be the SOI layer. Then, devices such as MOS transistors are formed in this SOI layer in similar manner as in FIG. 14. The subsequent procedure is identical to that of the semiconductor device manufacturing method according to the first preferred embodiment, so that the description thereof is omitted.

According to this preferred embodiment, the semiconductor wafers 11 and 320 are bonded together so that the same crystal orientations of the surfaces of the semiconductor wafers 11 and 320 are displaced at a predetermined angle with respect to each other. Further, using the SIMOX technique, the buried insulating layer 2 is formed in the semiconductor layers 31 and 32, and the surface-side portions of the semiconductor layers 31 and 32 above the buried insulating layer 2 become the SOI layer.

Accordingly, the surface of the SOI layer 31 formed by epitaxial growth is in the same crystal plane as the surface of the semiconductor wafer 11, but the surface of the SOI layer 32 which was the semiconductor wafer 320 is in a different crystal plane. That is, the SOI layers 31 and 32 can have different crystal orientations along a predetermined direction. Thus, it is possible to fabricate SOI substrate with a plurality of different crystal orientations mixed in its surface and with buried insulating layers formed in respective areas.

### Third Preferred Embodiment

This preferred embodiment is a modification of the semiconductor device manufacturing method according to the second preferred embodiment, in which SOI substrates are fabricated by bonding the bulk substrate of FIG. 33 to another semiconductor wafer with insulating layers formed thereon.

As in the second preferred embodiment, a bulk substrate with a plurality of different crystal orientations mixed in its surface is obtained through the process steps shown in FIGS. 23 to 33.

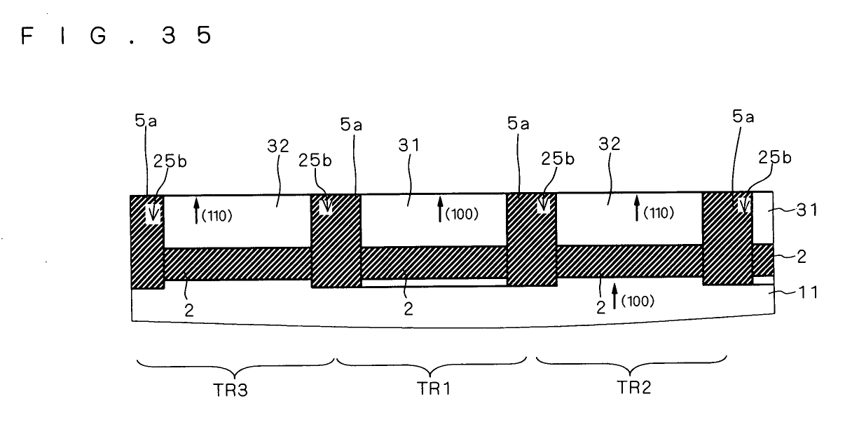

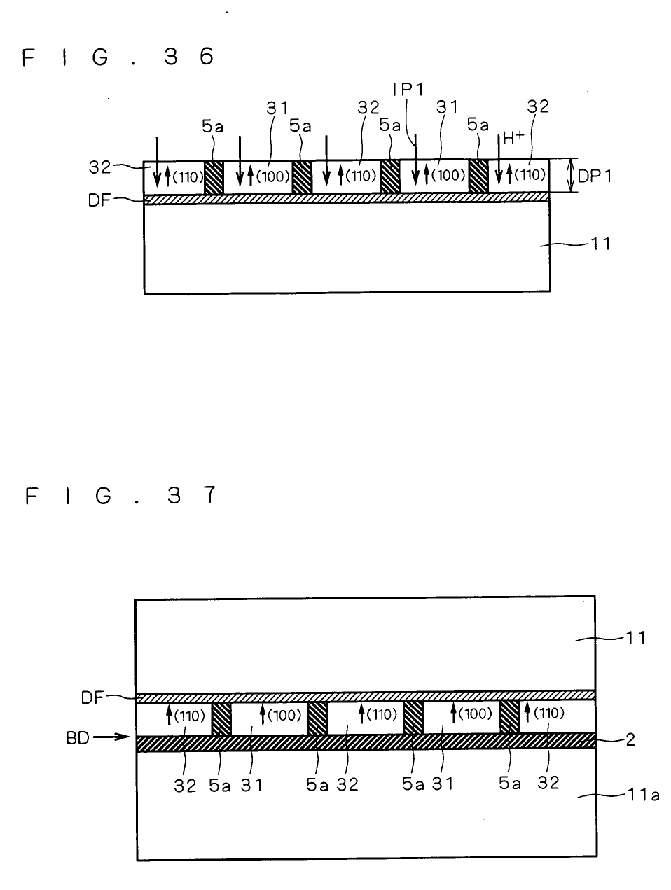

Then, the crystal defect layer DF is formed at the predetermined depth DP1 from the surface of this bulk substrate by the hydrogen ion implantation IP1 (FIG. 36). Then, as shown in FIG. 37, the bulk substrate of FIG. 36 is bonded to the surface of a semiconductor wafer 11a, such as a silicon wafer, with the insulating layer 2 such as silicon oxide film formed thereon. In FIG. 37, the bonding surface is indicated by BD.

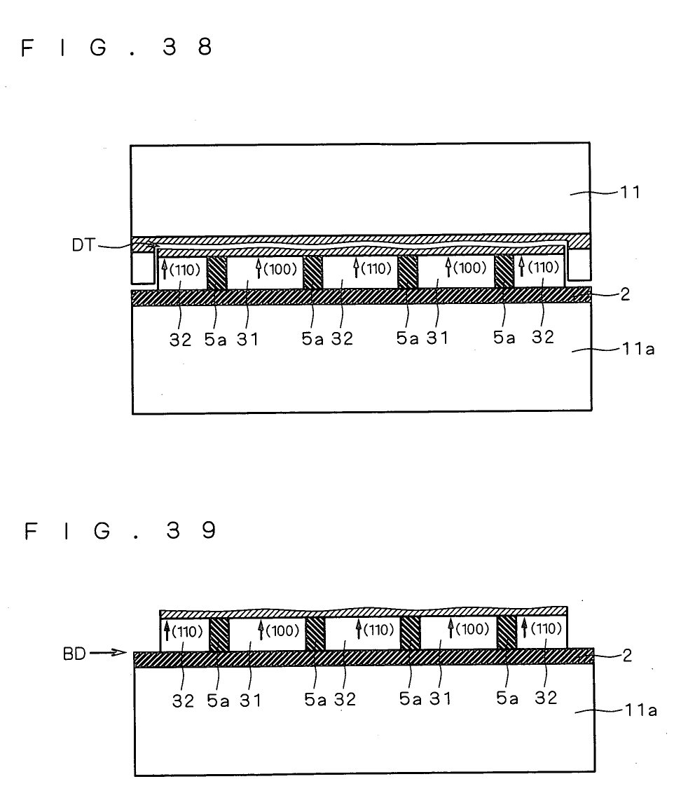

Then, the crystal defect layer DF is weakened by heat treatment, and the bulk substrate is split at the crystal defect layer DF as shown in FIG. 38. At this time, the outer edge of the bulk substrate is also removed because of weak bonding strength. In FIG. 38, the split surface is indicated by DT.

In the condition of FIG. 39, additional heat treatment is applied to increase the bonding strength between the insulating layer 2, and the semiconductor layers 31, 32 and the complete isolation insulating film 5a on the surface of the bulk substrate, and the surfaces of the semiconductor layers 31 and 32 are lightly polished to remove the remaining crystal defect layer. This produces an SOI substrate. That is, the bulk substrate after bonding is thinned to form an SOI substrate with the semiconductor wafer 11a as a supporting substrate, the insulating layer 2 as a buried insulating layer, and the semiconductor layers 31 and 32 as an SOI layer.

While in the present example the SMART CUT technology is used as an example of the methods for forming SOI substrates, other methods may be used instead. For example, a bonded bulk substrate may be thinned by CMP to form an SOI substrate.

With the semiconductor layers 31 and 32 as the SOI layer, devices such as MOS transistors are formed in this SOI layer in similar manner as in FIG. 14. The subsequent procedure is identical to that of the semiconductor device manufacturing method according to the first preferred embodiment, so that the description thereof is omitted.

According to this preferred embodiment, the semiconductor wafers 11 and 320 are bonded together so that the same crystal orientations of the surfaces of the semiconductor wafers 11 and 320 are displaced at a predetermined angle with respect to each other. Further, the semiconductor layers 31 and 32 on the surface of the bulk substrate obtained by bonding are bonded to the surface of the semiconductor wafer 11a with the insulating layer 2 formed thereon, thereby to form the SOI substrate with the semiconductor layers 31 and 32 as the SOI layer and the insulating layer as a buried insulating layer.

Accordingly, as in the case of the second preferred embodiment, the surface of the SOI layer 31 formed by epitaxial growth is in the same crystal plane as the surface of the semiconductor wafer 11, but the surface of the SOI layer 32 which was the semiconductor wafer 320 is in a different crystal plane. That is, the SOI layers 31 and 32 can have different crystal orientations along a predetermined direction. Thus, it is possible to fabricate SOI substrates with a plurality of different crystal orientations mixed in its surface and with buried insulating layers formed in respective areas.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a supporting substrate having a surface divided into at least first and second regions;
a first buried insulating layer provided on said surface of said supporting substrate in said first region;
a second buried insulating layer provided on said surface of said supporting substrate in said second region;
a first SOI (Semiconductor On Insulator) layer provided on said first buried insulating layer; and
a second SOI layer provided on said second buried insulating layer, said first and second SOI layers having different crystal orientations along a predetermined direction.

2. The semiconductor device according to claim 1, wherein
said first and second buried insulating layers have different thicknesses.

3. The semiconductor device according to claim 1, wherein
said first and second SOI layers have different thicknesses.

4. The semiconductor device according to claim 1, further comprising:
a complete element isolation film formed in said first or second SOI layer to reach said first or second buried insulating layer; and
a partial element isolation film formed in said first or second SOI layer not to reach said first or second buried insulating layer.

5. A semiconductor device manufacturing method comprising the steps of:
(a) forming an insulating layer on the surface of a first semiconductor wafer;
(b) bonding said insulating layer on said first semiconductor wafer to the surface of a second semiconductor wafer so that the same crystal orientations of said surfaces of said first and second semiconductor wafers are displaced at a predetermined angle with respect to each other;
(c) thinning said first semiconductor wafer after bonding to form an SOI (Semiconductor On Insulator) substrate with said second semiconductor wafer as a supporting substrate, said insulating layer as a first buried insulating layer, and a remainder of said first semiconductor wafer as a first SOI layer;
(d) using photolithographic and etching techniques, removing part of said first SOI layer and said first buried insulating layer to expose said supporting substrate;
(e) using an epitaxial growth technique, forming a semiconductor layer in the exposed area of said supporting substrate; and
(f) using a SIMOX (Separation by IMplanted OXygen) technique, forming a second buried insulating layer in said semiconductor layer so that a surface-side portion of said semiconductor layer above said second buried insulating layer becomes a second SOI layer.

6. The semiconductor device manufacturing method according to claim 5, wherein
in said step (f), the formation of said second buried insulating layer using said SIMOX technique is performed after an ion implantation stopping film is selectively formed on the surface of said SOI substrate.

7. A semiconductor device manufacturing method comprising the steps of:
(a) bonding first and second semiconductor wafers together so that the same crystal orientations of the surfaces of said first and second semiconductor wafers are displaced at a predetermined angle with respect to each other;
(b) thinning said first semiconductor wafer after bonding to form a bulk substrate with said second semiconductor wafer as a supporting substrate and a remainder of said first semiconductor wafer as a first semiconductor layer;
(c) using photolithographic and etching techniques, removing part of said first semiconductor layer to expose said supporting substrate;
(d) using an epitaxial growth technique, forming a second semiconductor layer in the exposed area of said supporting substrate; and
(e) using a SIMOX (Separation by IMplanted OXygen) technique, forming first and second buried insulating layers in said first and second semiconductor layers, respectively, so that a surface-side portion of said first semiconductor layer above said first buried insulating layer becomes a first SOI (Semiconductor On Insulator) layer and a surface-side portion of said second semiconductor layer above said second buried insulating layer becomes a second SOI layer.

8. A semiconductor device manufacturing method comprising the steps of:
(a) bonding first and second semiconductor wafers together so that the same crystal orientations of the surfaces of said first and second semiconductor wafers are displaced at a predetermined angle with respect to each other;
(b) thinning said first semiconductor wafer after bonding to form a bulk substrate with said second semiconductor wafer as a first supporting substrate and a remainder of said first semiconductor wafer as a first semiconductor layer;
(c) using photolithographic and etching techniques, removing part of said first semiconductor layer to expose said first supporting substrate;
(d) using an epitaxial growth technique, forming a second semiconductor layer in the exposed area of said first supporting substrate;
(e) bonding said first and second semiconductor layers on the surface of said bulk substrate to the surface of a third semiconductor wafer with an insulating layer formed thereon; and
(f) thinning said bulk substrate after bonding to form an SOI substrate with said third semiconductor wafer as a second supporting substrate, said first and second semiconductor layers as first and second SOI (Semiconductor On Insulator) layers, and said insulating layer as a buried insulating layer.
